(19) United States
(12) Patent Application Publication
(10) Pub. No.: US 2007/0131951 A1
(43) Pub. Date: Jun. 14, 2007

(54) Light-emitting element and making method thereof

(75) Inventors: Yuhei Ikemoto, Aichi-ken (JP); Koji Hirata, Aichi-ken (JP); Kazuo Aoki, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignees: TOYODA GOSEI CO., LTD., Aichi-ken (JP); KOHA CO., LTD., Tokyo (JP)

(21) Appl. No.: 11/634,381

(22) Filed: Dec. 6, 2006

(30) Foreign Application Priority Data
Dec. 14, 2005 (JP) 2005-360442

(51) Int. Cl. H01L 33/00

(52) U.S. Cl. 257/94

(57) ABSTRACT

A light-emitting element having: a gallium oxide substrate on a front surface of which a crystal of a semiconductor material having a light-emitting element part is grown; and a substrate protection layer formed on a back surface of the gallium oxide substrate. A method of making a light-emitting element having the steps of: forming a substrate protection layer on a back surface of a gallium oxide substrate; growing a crystal of a semiconductor material having a light-emitting element part on a front surface of the gallium oxide substrate; and assembling the light-emitting element so as to form a electrical connection for the light-emitting element part.

The present application is based on Japanese patent application No. 2005-360442, the entire contents of which are incorporated herein by reference.

### BACKGROUND OF THE INVENTION

1. Field of the Invention

This invention relates to a light-emitting element and, in particular, to a light-emitting element that is formed by growing a crystal on a gallium oxide substrate having a substrate protection layer. Also, this invention relates to a method of making the light-emitting element.

2. Description of the Related Art

Conventionally, a light-emitting element comprising a substrate composed of SiC, and laminated layers of n-type layer and p-type layer formed on the substrate, the layers composed of GaN is known (for example, JP-A-2002-255692 referred as a patent document 1).

On the other hand, in order to obtain a light-emitting element which comprises a substrate transmitted by a light of an ultraviolet part, so that a colorless and transparent conductive material transmitting a light from a visible part to an ultraviolet part can be provided, a vertical electrode structure can be formed by using the conductive material as the substrate, and a surface of a substrate side can also function as a surface of taking out the light, a light-emitting element comprising a gallium oxide substrate and a light-emitting element formed on the substrate is developed (for example, JP-A-2004-56098 referred as a patent document 2).

However, the light-emitting element shown in the patent document 1 uses NH3 as a nitrogen source and hydrogen gas as a carrier gas in a process of growing an epitaxial layer such as GaN layer, so that a gallium oxide substrate, in particular, a Ga₂O₃ substrate is etched in a back surface thereof by the hydrogen gas, and a permeability is decreased and a planarity of the substrate is deteriorated.

In the etching attack of the hydrogen gas, a damage by a high temperature heat treatment (for example, a heat treatment at 1100° C.) and a damage by a low temperature heat treatment (for example, a heat treatment at 650° C.) are can be observed. observing etching marks due to the damage by SEM, it is recognized that (010) face and (100) face in particular are to be etched easily. However, even if an epitaxial growth face is allocated as (001) face, the etching would become large from fine scratches in a back surface side of the substrate, so that it is difficult to grow a crystal without generating the etching marks in the back surface side of the substrate.

Therefore, in order to take out an output light from the back surface of the substrate in a light-emitting element formed by growing a GaN layer etc. on a gallium oxide substrate, it is required that the back surface of the substrate is planarized by a polishing process, and further in a making process of the light-emitting element nonflatness of the back surface of the substrate adversely affects a growing process of a compound semiconductor variously.

### SUMMARY OF THE INVENTION

It is an object of the invention to provide a light-emitting element formed on a gallium oxide substrate which is not affected by an etching attack of a hydrogen gas used in a growing process of a compound semiconductor, and comprises a good flatness and transparency thereof.

It is a further object of the invention to provide a method of making the light-emitting element.
(1) According to one embodiment of the invention, a light-emitting element comprises:

a gallium oxide substrate on a front surface of which a crystal of a semiconductor material comprising a light-emitting element part is grown; and

a substrate protection layer formed on a back surface of the gallium oxide substrate.

In the above embodiment (1), the following modifications and changes can be made.

(i) The substrate protection layer comprises an electrical conductivity so as to function as an-electrode.

(ii) The gallium oxide substrate comprises a Ga₂O₃ substrate.

(iii) The substrate protection layer comprises a material selected from TiN, W, WSi, BP, Al₂O₃, Mo, Ta, GaN, and AlN.
(2) According to another embodiment of the invention, a method of making a light-emitting element comprises the steps of:

forming a substrate protection layer on a back surface of a gallium oxide substrate;

growing a crystal of a semiconductor material comprising a light-emitting element part on a front surface of the gallium oxide substrate; and

assembling the light-emitting element so as to form a electrical connection for the light-emitting element part.

In the above embodiment (2), the following modifications and changes can be made.

(iv) The gallium oxide substrate comprises a Ga₂O₃ substrate.

(v) The substrate protection layer comprises a material selected from TiN, W, WSi, BP, Al₂O₃, Mo, Ta, GaN, and AlN.

(vi) The assembling step comprises a step of removing the substrate protection layer.

(vii) The substrate protection layer comprises an electrically nonconductive material.

(viii) The substrate protection layer comprises Al₂O₃ or AlN.

In the above embodiment (1) or (2), the following modifications and changes can be made.

(ix) The light-emitting element further comprising: a submount on which the light emitting element is mounted, wherein the submount comprises a Zener diode.

(x) The assembling step comprises a step of mounting the light-emitting element on a submount comprising a Zener diode.

### Advantages of the Invention

According to the invention, a light-emitting element formed on a gallium oxide substrate which is not affected by an etching attack of a hydrogen gas used in a growing process of a compound semiconductor, and comprises a good flatness and transparency thereof, and a method of making the light-emitting element can be provided.

### BRIEF DESCRIPTION OF THE DRAWINGS

The preferred embodiments according to the invention will be explained below referring to the drawings, wherein:

FIG. 1 is a cross sectional view showing a gallium oxide substrate as a growth substrate for forming a light-emitting element;

FIG. 2 is an explanatory block diagram showing a MOCVD method and a cross sectional view showing a main part of a MOCVD device;

FIG.3 is a cross sectional view showing a LED as a light-emitting element in a first preferred embodiment according to the invention,;

FIG. 4 is a cross sectional view showing a LED as a light-emitting element in a second preferred embodiment according to the invention;

FIG. 5 is a cross sectional view showing a LED as a light-emitting element in a third preferred embodiment according to the invention; and

FIG. 6 is a cross sectional view showing a LED as a light-emitting element in a fourth preferred embodiment according to the invention.

### DETAILED DESCRIPTION OF THE PREFERRED EMBODIMENTS

### First Embodiment

Composition of gallium oxide Substrate

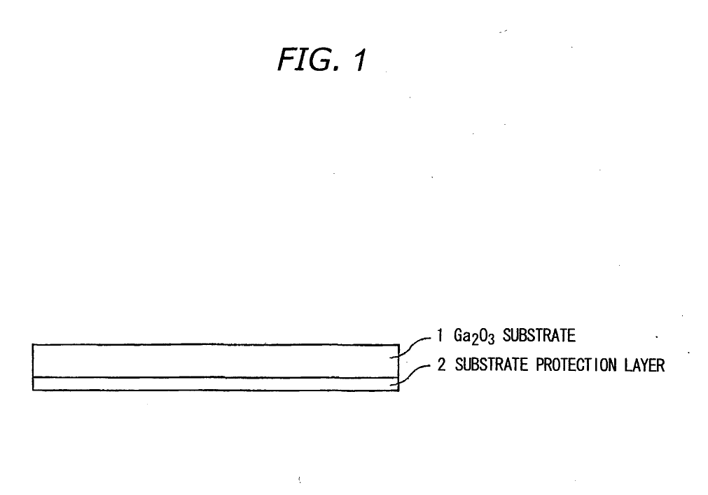

FIG.1 is a cross sectional view showing a gallium oxide substrate as a growth substrate for forming a light-emitting element. As examples of the gallium oxide substrate, a Ga₂O₃ substrate, in particular, a β-Ga₂O₃ substrate can be cited. Hereinafter, a case using a Ga₂O₃ substrate as the gallium oxide substrate will be explained.

On one surface of the Ga₂O₃ substrate 1 a substrate protection layer 2 is formed by a CVD method, a sputtering method etc. It is preferable that the substrate protection layer 2 is composed of a material comprising a heat resistance of 1200° C., and as its example TiN, W, WSi, BP, Al₂O₃, Mo, Ta, GaN, or AlN can be cited. TiN, W, WSi, and BP comprising an electrical conductivity are more preferable among the materials. In this embodiment, TiN comprising an electrical conductivity is used as the substrate protection layer 2. Further, it is preferable that the substrate protection layer 2 comprises at least such a degree of thickness as pin holes do not occur, for example, the thickness of 500 to 5000 angstrom is preferable.

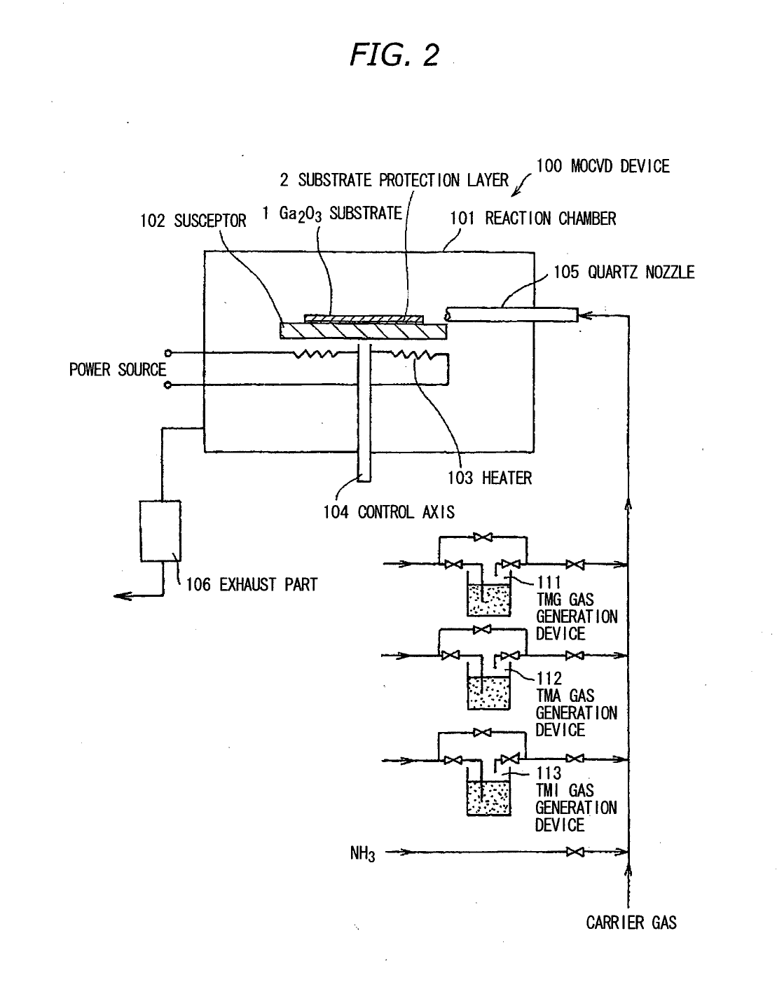

FIG.2 is an explanatory block diagram showing a MOCVD method and a cross sectional view showing a main part of a MOCVD device. The MOCVD device 100 comprises a reaction chamber 101 to which an exhaust part 106 comprising a vacuum pump and an exhaust device (not shown) is connected, a susceptor 102 mounting a Ga₂O₃ substrate 1, a heater 103 heating the susceptor 102, a control axis 104 rotating the susceptor 102 and moving it in a vertical direction, a quartz nozzle 105 supplying a material gas at a slant or at an evenness to the Ga₂O₃ substrate 1, and gas generation devices generating various material gases, such as a TMG (trimethylgallium) gas generation device 111, a TMA (trimethylaluminum) gas generation device 112, and a TMI (trimethylindium) gas generation device 113. Further, according to need, a number of the gas generation device can be increased or decreased. As a nitrogen source NH₃ can be used and as a carrier gas a hydrogen gas can be used. When a GaN film is formed the TMG and NH₃, are used, when AlGaN film is formed the TMA TMG and NH₃ are used, and when InGaN film is formed the TMI, TMG and NH₃ are used. The film is formed by the MOCVD device 100 as follows. First, the Ga₂O₃ substrate 1 is held on the susceptor 102, facing a surface where the substrate protection layer 2 is disposed to a downward side and facing a surface where the film is to be formed to an upward side, and is housed in the reaction chamber 101.

Composition of LED Element

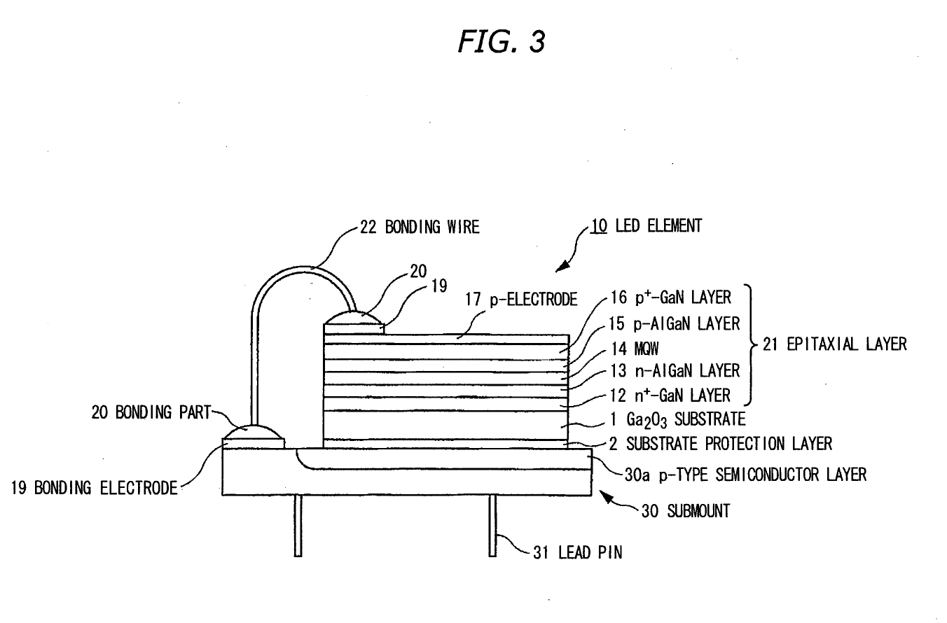

FIG. 3 is a cross sectional view showing an LED as a light-emitting element in a first preferred embodiment according to the invention.

A LED element 10 comprises a Ga₂O₃ substrate 1 comprising a conductivity type of n-type. And the LED element 10 comprises a n⁺-GaN layer 12 being Si-doped, a n-AlGaN layer 13 being Si-doped, a MQW (Multiple-Quantum-Well) 14 comprising a multiquantum well structure of a InGaN/GaN, a p-AlGaN layer 15 being Mg-doped, a p⁺-GaN layer 16 being Mg-doped and a p-electrode 17 composed of ITO (Indium Tin Oxide), being laminated on the Ga₂O₃ substrate 1 in order. And further the LED element 10 comprises a substrate protection layer 2 disposed on an under surface of the Ga₂O₃ substrate 1.

The n⁺-GaN layer 12 and the p⁺-GaN layer 16 are formed by supplying NH₃ and a trimethylgallium (TMG) gas into the reactor where the Ga₂O₃ substrate 1 is disposed, using N₂ as a carrier gas in a growth temperature condition of 1100° C. As to the n⁺-GaN layer 12, a monosilane (SiH₄) as a dopant for giving a conductivity type of n-type is used as a Si material, and as to the p⁺-GaN layer 16, a cyclopentadienyl magnesium (Cp₂Mg) as a dopant for giving a conductivity type of p-type is used as a Mg material. The n-AlGaN layer 13 and the p-AlGaN layer 15 are formed by supplying a trimethylaluminum (TMA) gas to the reactor in addition to the materials described above.

The MQW 14 is formed by supplying a trimethylindium (TMI) gas and a trimethylgallium (TMG) gas into the reactor using H₂ as a carrier gas in a growth temperature condition of 1100° C. When the InGaN is formed the TMI gas and the TMG gas are supplied, and when the GaN is formed the TMG gas are supplied.

Making Process of LED Element

First, a Ga₂O₃ substrate 1 is mounted on a susceptor 102 in a MOCVD device 100, facing a surface where the substrate protection layer 2 is disposed to a downward side.

Forming of GaN

Next, after being raised to a predetermined temperature (400° C.), a supply of N₂ is started. Subsequently, a temperature rising in the reactor is started, and the temperature rising is stopped at 1100° C., and then the temperature is maintained and the TMG gas of 60 sccm is supplied, so that the n⁺-GaN layer 12 of 1 μm thickness is formed. Next, a supply of N₂ is stopped and H₂ is supplied.

Subsequently, the n-AlGaN layer 13, the MQW 14, the p-AlGaN layer 15, the p⁺-GaN layer 16, and the p-electrode 17 are formed in order.

A plurality of the light-emitting elements formed on the Ga₂O₃ substrate 1 according to the process described above are cut to an individual light-emitting element by a dicing process etc., so that a bear chip is produced.

Further, a light-emitting element comprising a MQW structure has been explained, but the invention can also be applied to a hetero structure, a double hetero structure, and a single quantum well structure similarly.

Assembly of Light-emitting Element

Each of the bear chips cut out from the Ga₂O₃ substrate 1 is assembled into a light-emitting device according to the following process.

A light-emitting element comprising the Ga₂O₃ substrate 1, the epitaxial layer 21, and the p-electrode 17 is mounted on a submount 30 comprising lead pins 31 inserted and connected to a circuit substrate etc. through a conductive metal paste etc. The submount 30 is composed of a silicon substrate of n-type so as to operate as a zener diode for protecting the LED element 1 from a static electricity. The substrate protection layer 2 comprising an electrical conductivity is electrically connected to a p-type semiconductor layer 30a formed on the submount 30. The p-electrode 17 is electrically connected to the submount 30 through a bonding part 20 by a bonding wire 22. According to the process described above, a light-emitting element unit capable of being mounted to a circuit board etc. is completed.

### Advantages of the First Embodiment

According to the first preferred embodiment, the Ga₂O₃ substrate 1 is not affected by an etching attack of a hydrogen gas used in an epitaxial growing process of the Ga₂O₃ substrate 1 so as to maintain a good flatness and realize a high transparency, so that a light-emitting element comprising the Ga₂O₃ substrate 1 and a method of making the element can be provided.

Further, the substrate protection layer 2 is composed of a material comprising an electrical conductivity and is able to function as an n-electrode so as to perform two functions, so that a light-emitting element comprising a high productivity and a low cost can be provided. Furthermore, the transparency of the Ga₂O₃ substrate 1 is maintained, so that a composition of taking out an output light of the light-emitting element from a back surface of the substrate can be adopted.

### Second Embodiment

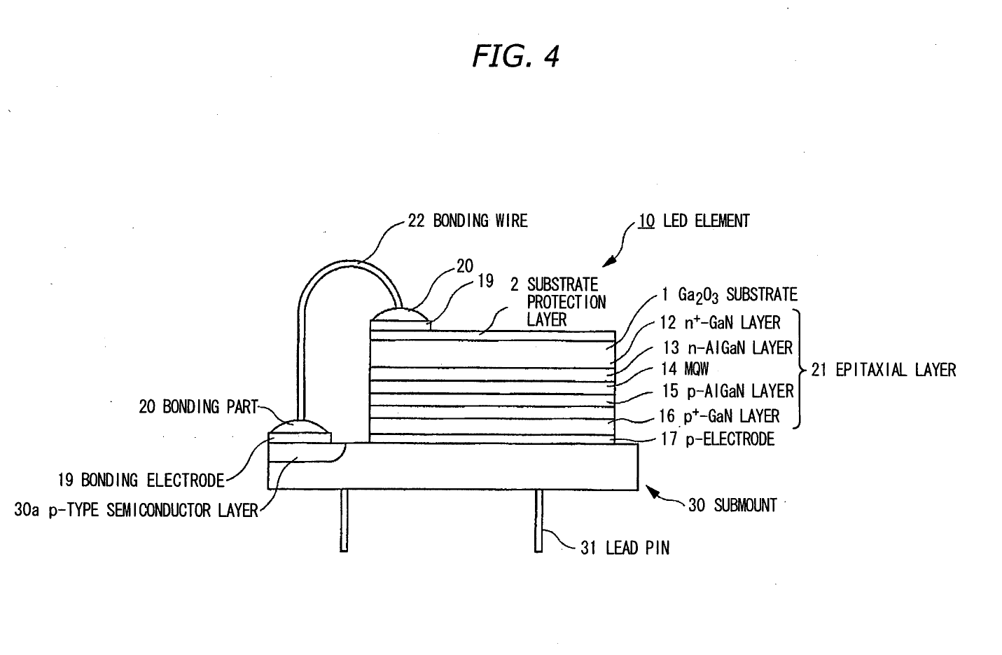

FIG.4 is a cross sectional view showing a LED as a light-emitting element in a second preferred embodiment according to the invention.

A light-emitting element 10 according to the second preferred embodiment is different from the first preferred embodiment in a composition that a vertical location of a p-side and a n-side to the submount 30 are disposed in a direction opposite to the first preferred embodiment. That is, each of the bear chips cut out from the Ga₂O₃ substrate 1 is assembled into a light-emitting device according to the following process. The p-electrode 17 is mounted on the submount 30 through a conductive metal paste etc. The substrate protection layer 2 composed of TiN comprising an electrical conductivity can function as an n-electrode, so as to be electrically connected to the p-type semiconductor layer 30a formed on the submount 30 through a bonding electrode 19 and a bonding part 20 by a bonding wire 22. According to the process described above, a light-emitting element unit capable of being mounted to a circuit board etc. is completed.

### Third Embodiment

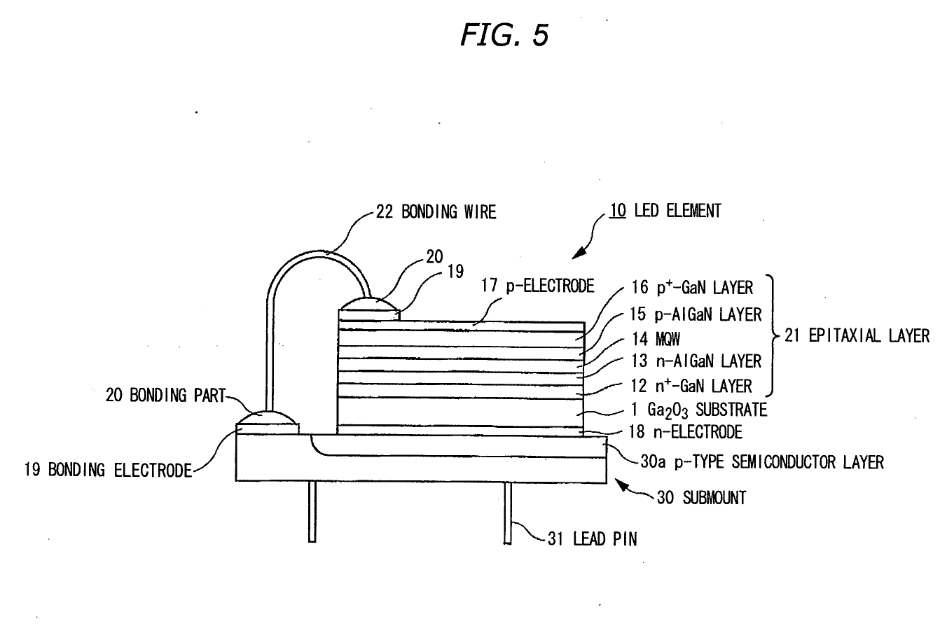

FIG.5 is a cross sectional view showing a LED as a light-emitting element in a third preferred embodiment according to the invention.

A light-emitting element 10 according to the third preferred embodiment is different from the first preferred embodiment in a composition that AlN of a nonconductive material is used as the substrate protection layer 2. The epitaxial layer 21 is formed by a MOCVD method as same as the first preferred embodiment, after that the substrate protection layer 2 is removed by removing methods such as a polishing method, a CMP (Chemical Mechanical Polishing) method, an etching method.

After the removal of the substrate protection layer 2, a patterning is formed on both surfaces of the epitaxial layer 21 by using a photolithography technique, and the p-electrode 17 and n-electrode 18 are formed by a vapor deposition method.

The light-emitting element formed on the Ga₂O₃ substrate 1 according to the process described above are cut to an individual light-emitting element by a dicing process etc., so that a bear chip is produced.

Assembly of Light-emitting Element

Each of the bear chips cut out from the Ga₂O₃ substrate 1 is assembled into a light-emitting device according to the following process.

A light-emitting element comprising the Ga₂O₃ substrate 1, the epitaxial layer 21, the p-electrode 17 and the n-electrode 18 is mounted on a submount 30 comprising lead pins 31 inserted and connected to a circuit substrate etc. through a conductive metal paste etc. The submount 30 is composed of a silicon substrate of n-type so as to operate as a zener diode for protecting the LED element 10 from a static electricity. The n-electrode 18 is electrically connected to a p-type semiconductor layer 30a formed on the submount 30. The p-electrode 17 is electrically connected to the submount 30 through a bonding electrode 19 and a bonding part 20 by a bonding wire 22. According to the process described above, a light-emitting element unit capable of being mounted to a circuit board etc. is completed.

### Advantages of the Third Embodiment

According to the third preferred embodiment, in addition to the advantages of the first preferred embodiment, a nonconductive material can be used as the substrate protection layer 2 so that a range of choices for the material can be expanded and a restriction on a making process can be decreased.

### Fourth Embodiment

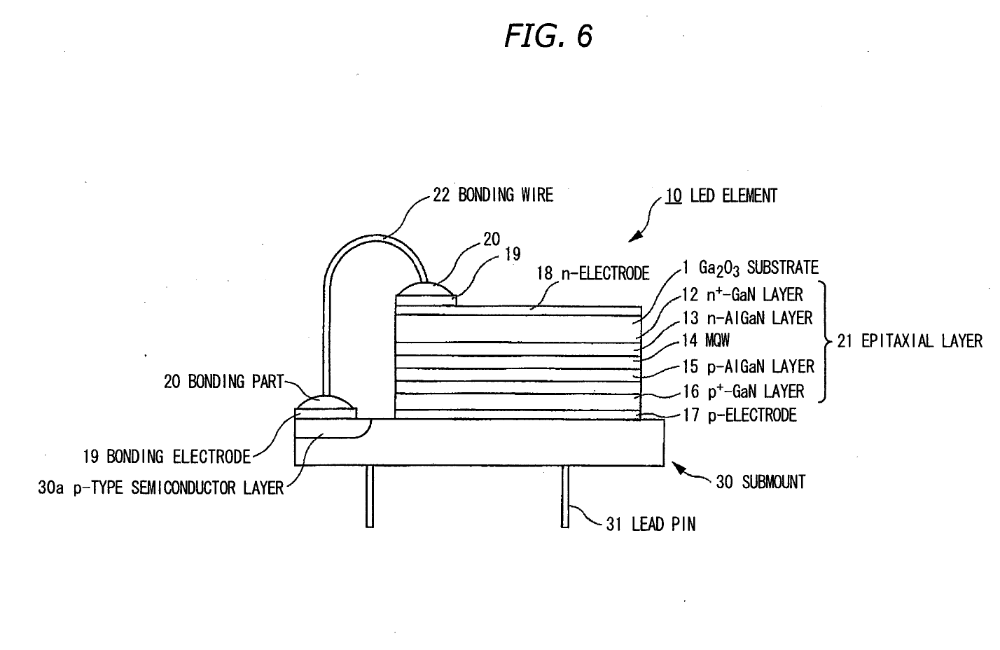

FIG.6 is a cross sectional view showing a LED as a light-emitting element in a fourth preferred embodiment according to the invention.

A light-emitting element 10 according to the fourth preferred embodiment is different from the third preferred embodiment in a composition that a vertical location of a p-side and a n-side to the submount 30 are disposed in a direction opposite to the third preferred embodiment. That is, each of the bear chips cut out from the Ga₂O₃ substrate 1 is assembled into a light-emitting device according to the following process. The p-electrode 17 is mounted on the submount 30 through a conductive metal paste etc. The n-electrode18 is electrically connected to the p-type semiconductor layer 30a formed on the submount 30 through a bonding electrode 19 and a bonding part 20 by a bonding wire 22. According to the process described above, a light-emitting element unit capable of being mounted to a circuit board etc. is completed.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A light-emitting element, comprising:
a gallium oxide substrate on a front surface of which a crystal of a semiconductor material comprising a light-emitting element part is grown; and
a substrate protection layer formed on a back surface of the gallium oxide substrate.

2. The light-emitting element according to claim 1, wherein:
the substrate protection layer comprises an electrical conductivity so as to function as an-electrode.

3. The light-emitting element according to claim 1, wherein:
the gallium oxide substrate comprises a Ga₂O₃ substrate.

4. The light-emitting element according to claim 1, wherein:
the substrate protection layer comprises a material selected from TiN, W, WSi, BP, Al₂O₃, Mo, Ta, GaN, and AlN.

5. A method of making a light-emitting element, comprising the steps of:
forming a substrate protection layer on a back surface of a gallium oxide substrate;
growing a crystal of a semiconductor material comprising a light-emitting element part on a front surface of the gallium oxide substrate; and
assembling the light-emitting element so as to form a electrical connection for the light-emitting element part.

6. The method according to claim 5, wherein:
the gallium oxide substrate comprises a Ga₂O₃ substrate.

7. The method according to claim 5, wherein:
the substrate protection layer comprises a material selected from TiN, W, WSi, BP, Al₂O₃, Mo, Ta, GaN, and AlN.

8. The method according to claim 5, wherein:
the assembling step comprises a step of removing the substrate protection layer.

9. The method according to claim 8, wherein:
the substrate protection layer comprises an electrically nonconductive material.

10. The method according to claim 9, wherein:
the substrate protection layer comprises Al₂O₃ or AlN.

11. The light-emitting element according to claim 1, further comprising:
a submount on which the light emitting element is mounted,
wherein the submount comprises a Zener diode.

12. The method according to claim 5, wherein:
the assembling step comprises a step of mounting the light-emitting element on a submount comprising a Zener diode.
